(19) United States
(12) Patent Application Publication
(10) Pub. No.: US 2010/0065810 A1
(43) Pub. Date: Mar. 18, 2010

(54) Method Of Synthesizing Semiconductor Nanostructures And Nanostructures Synthesized By The Method

(75) Inventors: Ulrich Goesele, Halle (DE); Stephan Senz, Halle (DE); Volker Schmidt, Halle (DE); Yewu Wang, Hangzhou (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Max-Planck-Gessellschaft zur Foerderung der Wissenschaften e.V., Munechen (DE)

(21) Appl. No.: 12/440,233

(22) PCT Filed: Apr. 5, 2007
(86) PCT No.: PCT/EP07/03120

§ 371 Date: Oct. 13, 2009

(30) Foreign Application Priority Data
Sep. 7, 2006 (EP) 06018800.0

(51) Int. Cl. H01L 29/66; H01L 21/20

(52) U.S. Cl. 257/9; 438/479; 257/E29.168; 257/E21.09; 977/762; 977/773

(57) ABSTRACT

A method of synthesizing semiconductor nanostructures of at least one semiconductor material (e.g. nanowires, nanorods, nanoribbons, nanodots, quantumdots, etc.) is described which includes the steps of placing a solid catalyst particle on a substrate, placing the combination of the said substrate and the said solid catalyst in a chamber of low oxygen partial pressure, below I×10⁻² mbar, adding one or more gaseous reactants comprising at least one of said semiconductor material and a suitable precursor therefor and heating the said combination to a temperature above 200° C. but below the melting point of the solid catalyst particle. Nanostructures made by the method are also claimed.

The invention relates to a method of synthesizing semiconductor nanostructures (e.g. nanowires, nanorods, nanoribbons, nanodots, quantumdots, etc.) and to nanostructures synthesized by the method.

A variety of methods of synthesizing nanostructures for potential use in small-scale devices has been demonstrated and described. A very prominent method is based on growing the nanostructure by using a metal catalyst particle and supplying the semiconductor material by gaseous reactants. This technique for the growth of semiconductor crystals was developed in 1964 by Wagner and Ellis. In this connection, reference is made to the papers by R. S. Wagner and Ellis W. C. “Vapor-liquid-solid mechanism of single crystal growth” Appl. Phys. Lett., 4(5), 89.90, 1964 and R. S. Wagner, W. C. Ellis, K. A. Jackson and S. M. Arnold “Study of the filamentary growth of silicon crystals from the vapor” J. Appl. Phys., 35(10), 2993.3000, 1964. They named their technique the vapor-liquid-solid (VLS) growth method, since a gaseous semiconductor reactant is transformed by a liquid catalyst particle into a solid semiconductor crystal. They demonstrated the growth of acicular silicon crystal by using a liquid Au/Si catalyst droplet and SiCl₄ as precursor gas. A related method is based on the use of a solid catalyst particle, and it is therefore called vapor-solid-solid (VSS) growth technique.

In the meantime, a large variety of semiconductor nanostructures has been synthesized by the above mentioned growth methods using different catalyst materials. With respect to the growth of silicon or germanium nanowires and microwires, the different techniques can be classified into three groups:

(i) VLS growth at high temperatures >578° C.,
(ii) VLS growth at low temperatures <578° C.,
(iii) VSS growth using a solid suicide particle as catalyst.

(i) The high temperature (>578° C.) VLS growth of silicon nanowires and/or germanium nanowires or microwires has been demonstrated for the following catalyst materials: Fe, Ni, Pd, Pt, Cu, Ag, Au, Al, Ga, In, and others. In this connection, reference can be made to the following papers:

A. M. Morales and C. M. Lieber “A laser ablation method for the synthesis of crystalline semiconductor nanowires” Science, 279, 208.211, 1998;
Y. Osada, H. Nakayama, M. Shindo, T. Odaka and Y. Ogata “Growth and structure of silicon fibers” J. Electrochem. Soc., 126(1), 31.36, 1979;
E. I. Givargizov and N. N. Sheftal “Morphology of silicon whiskers grown by the VLS-technique” J. Cryst. Growth, 9, 326.329, 1971 and
R. S. Wagner and W. C. Ellis “The vapor-liquid-solid mechanism of crystal growth and its application to silicon” Trans. Met. Soc. AIME, 233, 053.1064, 1965. From a device point of view, the main disadvantage of this method is the high growth temperature. If the structures are produced in place on a suitable substrate, the application of a high synthesis temperature can be incompatible with pre-growth processing of the substrate. Furthermore, the high metal diffusion at the growth temperature used can cause problems.

(ii) A low temperature (<578° C.) VLS growth of silicon and/or germanium nanowires and microwires has been demonstrated for the following catalyst materials: Zn, Au, and Ga. In this connection, reference can be made to J.-Y. Yu, S.-W. Chung and J. R. Heath “Silicon nanowires: preparation, device fabrication, and transport properties” J. Phys. Chem. B, 104, 11864.11870, 2000; J. Westwater, D. P. Gosain, S. Tomiya and S. Usui “Growth of silicon nanowires via gold/silane vapor-liquid-solid reaction” J. Vac. Sci. Technol. B, 15(3), 554-557, 1997; V. Schmidt, S. Senz and U. Gösele “UHV chemical vapour deposition of silicon nanowires” Z. Metallkd., 96(5), 427.428, 2005 and M. K. Sunkara, S. Sharma, R. Miranda, G. Lian and E. C. Dickey “Bulk synthesis of silicon nanowires using a low-temperature vapor-liquid-solid method” Appl. Phys. Lett., 79(10), 1546.1548, 2001. The first two mentioned metals, Zn and Au, are known to create deep level defects in silicon and are therefore incompatible with existing electronics fabrication technology. The growth of silicon nanowires using Ga as a catalyst does not seem to be readily controllable. Furthermore, the low temperature eutectic point of a Ga/Si alloy (30° C.) provides an additional technological challenge. The best results up to now are achieved with Au as catalyst (see for example the paper by V. Schmidt, S. Senz and U. Gösele as cited above). One can see that an additional problem can be identified, namely the tendency of the nanowires to exhibit a high percentage of so-called kinks, i.e. spontaneous changes of the growth direction, which is of course undesired from a device point of view.

(iii) A VSS growth of silicon and/or germanium nanowires and microwires has been demonstrated for the following catalyst materials: Ti, Fe, Dy. In contrast to methods (i) and (ii), the crystalline quality of the wires is poor. Reference can be made here to T. I. Kamins, R. S. Williams, Y.-L. Chen and Y. A. Chang “Chemical vapor deposition of Si nanowires nucleated with TiSi2 islands on Si” Appl. Phys. Lett., 76(5), 562.564, 2000 and to the paper by V. Schmidt, S. Senz and U. Gösele as cited above.

The object underlying the present invention is to propose a method for the production of semiconductor nanowires which uses (a) a low growth temperature and (b) a catalyst that does not create deep level defects in the semiconductor in question, but, nonetheless, produces (c) single crystalline nanostructures of (d) well-defined and well-controllable geometry, that in addition (e) exhibit a small number of kinks.

In order to satisfy this object there is provided a method of synthesizing semiconductor nanostructures of at least one semiconductor material (e.g. nanowires, nanorods, nanoribbons, nanodots, quantumdots, etc.) by placing a solid catalyst particle on a substrate, placing the combination of the said substrate and the said solid catalyst in a chamber of low oxygen partial pressure, below 1×10⁻² mbar, adding one or more gaseous reactants comprising at least one of said semiconductor material and a suitable precursor therefor and heating the said combination to a temperature above 200° C. but below the melting point of the solid catalyst particle.

The invention thus relates to a method for the fabrication of crystalline nanostructures, by placing a catalyst particle mainly consisting of Al on a suitable substrate and placing the substrate in a chamber of low oxygen vapor pressure. The said substrate catalyst combination is heated in said chamber to a temperature between 200° C. and the melting point of the catalyst particle below 578° C. The semiconductor material is supplied by a gaseous reactant, containing the desired semiconductor material in question. In principle the semiconductor material can be generated in the chamber, which has a low pressure atmosphere of an inert gas such as argon, from a solid target using a physical vapor deposition (PVD) process such as electron beam evaporation, magnetron sputtering or arc sputtering. However, this may be relatively difficult to realize because a strong unwanted growth seems to occur at positions of the substrate not covered by the catalyst. At least this appears to be the case for the published result using electron beam evaporation of silicon and Au as catalyst (J. Cryst. Growth, 290, 6.10, 2006).

For these reasons it is preferable to supply the semiconductor material in gaseous form as a suitable precursor such as SiH₄ for the growth of silicon nanostructures and GeH₄ for the growth of germanium nanostructures.

The catalyst particle can be aluminum. In this case, the aluminum can combine with the semiconductor material of the substrate and/or with the gaseous semiconductor material to form the catalyst which typically has a relatively low silicon content. Alternatively, the catalyst particle can be given a suitable composition from the outset. It can, e.g. comprise more than 80 atomic % of Al and less than 20 atomic % of the semiconductor material. In a further alternative it can comprise more than 50 atomic % of Al, less than 20 atomic % of the semiconductor material and less than 30 atomic % of a combination of a different added metal.

The added metal is conveniently chosen from the group comprising: B, Al, Ga, In, Tl, Li, Sb, P, As, Bi, Te, Ti, Pt, Pd and combinations thereof.

The substrate is selected to comprise an epitaxial substrate having a surface lattice spacing equal to or approximately equal to that of the semiconductor material in epitaxial form, approximately signifying that the lattice spacing of the substrate surface differs from that of the semiconductor material by at most +/−20%.

The epitaxial substrate can be selected in the form of a semiconductor on insulator substrate.

The semiconductor material can be one of Si or Ge or a combination of Si and Ge and the substrate material is then conveniently selected to be Si or Ge respectively.

When used to produce Si/Ge, Si/SiGe, Ge/SiGe, or SiGe/SiGe heterostructure nanostructures the method is characterized by the alternate admission of one of the following semiconductor material combinations into said chamber either in vapor form, e.g. by a PVD process following sputtering or vaporization from respective solid targets or by using corresponding precursors in a CVD process:
Si and Ge,
Ge and (Si and Ge),
Si and (Si and Ge) and
Si and Ge in a first ratio and Si and Ge in a second ratio different from the first said ratio.

The invention will now be explained in more detail by way of example and with reference to the accompanying drawings in which are shown:

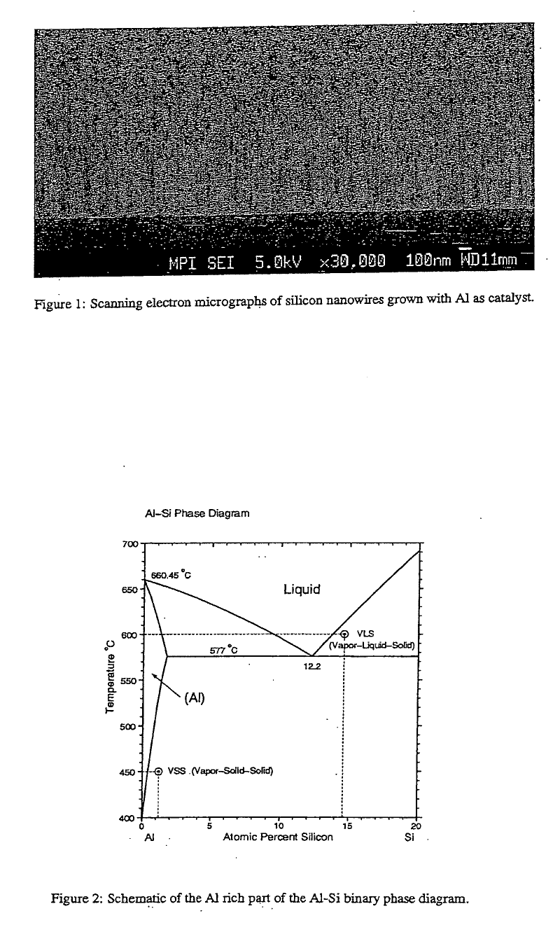

FIG. 1 a scanning electron micrograph of silicon nanowires grown with Al as a catalyst,

FIG. 2 a schematic diagram of the Al rich part of the Al—Si binary phase diagram, as prepared by T. B. Massalski, H. Okamoto, P. R. Subramanian and L. Kacprzak “Binary Alloy Phase Diagrams” volume 1. ASM International, Materials Park, Ohio, 2nd edition, 1990,

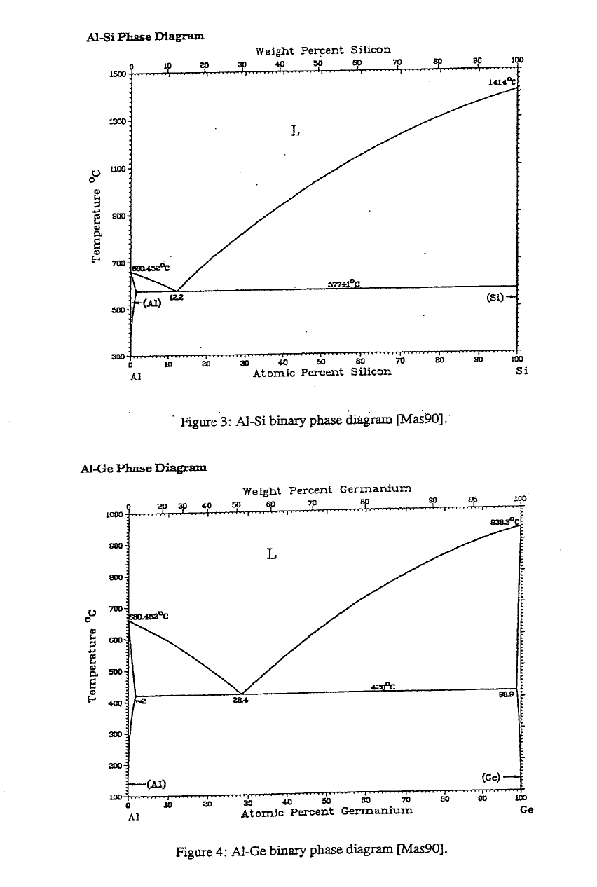

FIG. 3 the Al—Si phase diagram in full, also prepared by the authors named in connection with FIG. 2,

FIG. 4 the Al—Ge phase diagram in full, also prepared by the authors named in connection with FIG. 2,

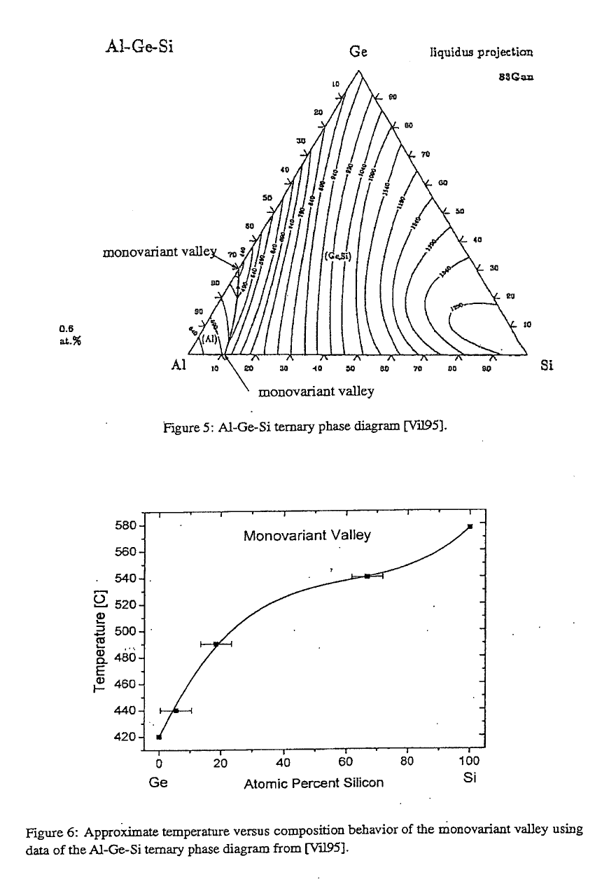

FIG. 5 the Al—Ge—Si ternary phase diagram as prepared by P. Villars, A. Prince and H. Okamoto “Handbook of ternary alloy phase diagrams” volume 4. ASM International, Materials Park, Ohio, 1995,

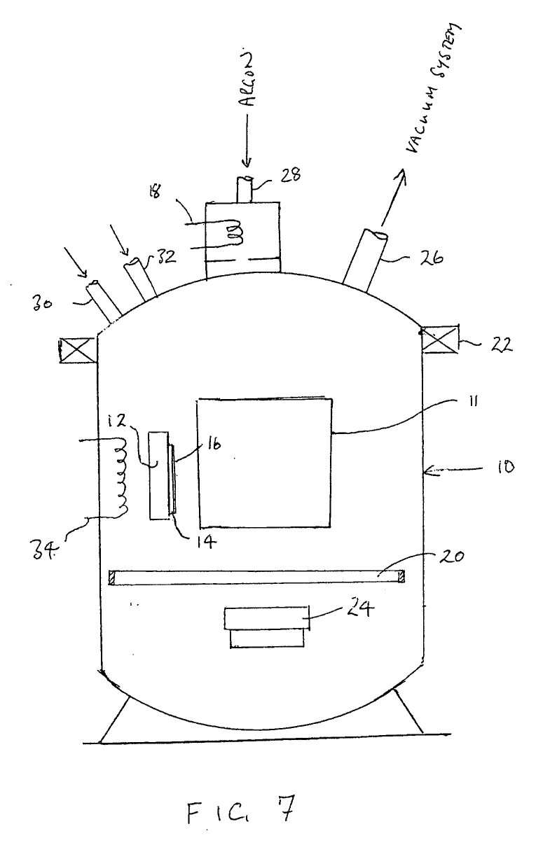

FIG. 6 the approximate temperature versus composition behavior of the monovariant valley of the phase diagram of FIG. 5 using data taken from that phase diagram and

FIG. 7 a schematic view of the apparatus used to carry out the method.

Turning first to FIG. 7 there can be seen a suitable CVD PVD apparatus for carrying out the method. The apparatus comprises a vacuum chamber 10 having an access door 11 and containing a substrate holder 12 for the semiconductor substrate 14 which has initially been provided with a thin layer of aluminum 16. The aluminum 16 can be deposited on the substrate 14 in the chamber using, for example, a source of electrons such as a heated tungsten filament 18 used to generate an electron beam which is accelerated by an anode 20 and focused by suitable magnetic means 22 onto an aluminum target 24 to generate an aluminum vapor in the chamber which condenses on the substrate 14.

The chamber has a suitable connection port 26 for connection via an on/off valve (not shown) to a vacuum system to evacuate the chamber 10 to the desired pressure of below 1×10⁻² mbar, a port 28 for admitting an inert gas such as argon to flush the chamber in combination with the vacuum system to rid it of oxygen and other undesired gases, or at least to reduce the quantities of unwanted gases to an acceptable level. In addition there is a further port 30 for admitting a gaseous precursor for the semiconductor material to the chamber. For the growth of silicon nanostructures this precursor can be SiH₄. For germanium it can be GeH₄. If alternating Si and Ge structures are to be grown then suitable precursors can be admitted alternately to the chamber through the port 30, via a two way valve (not shown) disposed upstream of the port 30 and connected to the sources of precursor material. Alternatively a further port such as 32 can be provided and each precursor can be directed to the respective port via a respective on/off valve (also not shown).

The chamber also contains a heater 34 which can be used to heat the substrate 14 with the aluminum layer to the desired temperature. In the first place a relatively high temperature can be selected which causes the aluminum to melt and form small droplets which act as the catalyst particles. The aluminium droplets are then statistically distributed on the substrate. Their mean size can be determined by controlling the thickness of the layer 16.

Alternatively a wafer 14 with a layer of aluminum 16 can be treated lithographically to provide distinct regularly oriented aluminum islands which act as catalyst particles.

When using the apparatus to grow the semiconductor structures the heater 34 is used to control the growth temperature as described. It should be noted that the above described apparatus is only one of many possible forms and has been described purely by way of example and not with any intended limitation.

Instead of using a CVD process to generate the semiconductor structures from a gaseous precursor or precursors a PVD process could also be used. For example, one or more targets of the required semiconductor material(s) can be provided (similarly to the Al target 24) and the electron beam can be focused onto the respective target to generate a vapor of the desired semiconductor material.

Briefly, the method in accordance with the present teaching involves the growth of crystalline nanostructures from a supersaturated solid catalyst particle situated between the vapor and the solid semiconductor material. In the operation of the process, the precursor impinges on the catalyst particle surface and the semiconductor atoms of the precursor gas are incorporated in the catalyst particle. The precursor molecules are split up at the surface of the particle. The semiconductor material which is released is incorporated into the particle and causes an oversaturation of the particle. As a result of the oversaturation, the semiconductor material is precipitated out of the particle in solid form which is associated with the growth of the nanostructure. The catalyst particle thus attains supersaturation resulting in the solidification of the semiconductor material at the catalyst-semiconductor interface and concurrent crystal growth. In FIG. 1 silicon nanowires synthesized with a solid Al particle can be seen. These wires are synthesized at a temperature around 450° C. One can see that the resulting Si nanowires have a well-defined length, diameter and orientation. Furthermore, especially in contrast to Si nanowire growth using Au as the catalyst, a much smaller density of kinks is found. TEM-investigations revealed that the nanowires are single crystalline. Thus, the VSS growth of silicon nanowires fulfills the criteria (a)-(e): (a) a synthesis temperature below 578° C., (b) a catalyst material that does not create deep level defects in the semiconductor, (c) single crystallinity, (d) a well-defined geometry, and (e) a small number of kinks.

Silicon nanowires were synthesized using the present teaching in the following manner:

(111) oriented epitaxial Si wafers were used as the substrate and were cleaned and dipped in dilute HF in order to obtain a hydrogen terminated Si surface. The so treated wafers were then placed in an UHV chamber such as 10 in FIG. 7 and were vapor-coated there with a thin layer (<1 nm) of Al. The coated wafers were subsequently heat-treated at ca. 600° C. in the chamber for a few minutes using the heater 34 in order to obtain Al—Si catalyst particles distributed statistically on the surface of the wafer. The UHV chamber 10 was then filled with diluted silane (5% in Argon) through port 30 at a substrate temperature of 450° C. (generated using the heater 34) at a pressure of up to 5 mbar. This state was maintained for ca. 20 minutes. In this way, homoepitaxial silicon nanowires of <111> orientation were produced as illustrated in FIG. 1.

The position of the supersaturated solid Al/Si particle in the temperature vs. composition Al/Si binary phase diagram during Si nanostructure synthesis is schematically depicted in FIG. 2, which shows a close-up of the Al-rich part of the Al/Si binary phase diagram of FIG. 3. In case of the vapor-solid-solid (VSS) growth of Si nanostructures, the synthesis temperature is smaller than the eutectic temperature 578° C. and the Si concentration is smaller than the eutectic concentration of 12.2%. During VSS growth, the catalyst particle is supersaturated with Si, which leads to the precipitation of Si at the catalyst/Si interface. Equivalent to a supersaturation, the Si concentration inside the Al catalyst particle is slightly higher than the equilibrium concentration at this temperature. Thus, the position of the catalyst particle in the phase diagram is on the right-hand side of the line separating the solid-Al phase from the solid-Al/solid-Si phase. Considering the phase diagram, it becomes clear that the synthesis method proposed herein using a solid particle differs substantially from the vapor-liquid-solid (VLS) growth mode using Al as catalyst as demonstrated by Osada et al. In this case the growth temperature is higher than the eutectic temperature 578° C. and the Si concentration is higher than the Si concentration at the eutectic point. Due to the supersaturation of the liquid Al/Si particle, the Si concentration is even higher than the equilibrium concentration defined by the liquidus-line separating the liquid Al/Si phase from the Al/Si-liquid/Si-solid phase. So the VSS growth takes place at a totally different position of the phase diagram than the VLS growth. To some degree the VSS growth technique is related to the solid-phase epitaxy (SPE) method [Poa78], but with the difference that a gaseous semiconductor precursor is used.

The Al/Si binary phase diagram, FIG. 3, is in many respects similar to the Al/Ge binary phase diagram FIG. 4. Thus a VSS growth of Ge nanowires using Al as catalyst should yield similar results. One favorable aspect of the VSS growth of Si or Ge nanowires is that, as shown in FIG. 3 and FIG. 4, the silicon concentration in the catalyst particle is smaller than about 2%. Thus the Si concentration is about one order of magnitude smaller than in the VLS growth using Al as catalyst. This is of special interest if axial Si/Ge heterostructures are to be produced, for the following reason: To produce an axial A-B heterostructure, the semiconductor material A has to be changed to material B, which might be done by changing the gaseous reactant, e.g. from SiH₄ to GeH₄ to produce a Si—Ge-heterostructure. Assuming a half-spherical particle, the volume of the particle is 4πr³/6, with r being the radius of the nanowire. The amount of semiconductor material A dissolved in the particle is C_{A}·4πr³/6, with C_{A} being the concentration of the semiconductor material A in the particle. After switching semiconductor A to B, the material A mixes with material B in the particle till material A is fully consumed by the growing wire. This causes a graded junction between the wire segment A and B with a characteristic width ω_{AB}=C_{A}·r/3. For producing a B-A transition, a characteristic width ω_{BA}=C_{B}·r/3 of the transition region can be expected. So if both A-B and B-A nanowire heterojunctions with atomically sharp interfaces are to be produced, the characteristic widths ω_{AB} and ω_{BA} have to be considerably smaller than the lattice spacing, being usually of the order of ⅓ nm. This leads to the criterion that both C_{A} and C_{B} have to be considerably smaller than 1 nm/r. For example, in order to produce a Si—Ge multiple heterostructure nanowire with 20 nm radius, both the Si and the Ge concentration in the catalyst particle has to be considerably less than 5%. Considering the VSS growth using a solid Al particle at about 400° C., the Si concentration in the catalyst particle is less than 1% (see FIG. 3) and the Ge concentration less than 2% (see FIG. 4). Thus, a fabrication of axial Si—Ge and Ge—Si heterojunctions with atomically sharp interfaces should be possible supposing the radius of the nanowire is less than 15-20 nm.

Care has to be taken that the catalyst particle remains solid while switching from Si to Ge or from Ge to Si. In FIG. 5 the ternary Al—Ge—Si phase diagram is depicted. In the ternary Al—Ge—Si system, the reaction L⇄Al+Si and L⇄Al+Ge are connected by a monovariant valley, L⇄Al+SiGe, falling from 578° C. at 12.2 at % Si to 424_C at 28.4 at % Ge (where L signifies a liquid). Using the data of FIG. 5, the approximate temperature versus composition curve of the monovariant valley is given in FIG. 6. This temperature versus composition curve is especially important having Si(SiGe), axial nanowire heterostructures in mind. In this case, the curve of FIG. 6 dictates the maximum synthesis temperature, e.g. for a Si-(0.8Si 0.2Ge) heterostructure, the synthesis temperature should be lower than about 480° C.

Thus the above method can be used to produce Si/Ge, Si/SiGe, Ge/SiGe, or SiGe/SiGe heterostructure nanostructures by the alternate admission of one of the following semiconductor material combinations into said chamber either in vapor form, e.g. by a PVD process following sputtering or vaporization from respective solid targets or by using corresponding precursors in a CVD process:
Si and Ge,
Ge and (Si and Ge),
Si and (Si and Ge) and
Si and Ge in a first ratio and Si and Ge in a second ratio different from the first said ratio, with the simplest possible nanostructure consisting of either Si or Ge or SiGe.

Moreover, the procedure of the above method can be repeated with identical or different parameters. In this way it is possible to produce a superlattice of Si and SiGe by repeating several times Si and SiGe, or a structure starting with one SiGe ratio and gradually changing the SiGe ratio. These are simply examples and are not intended to exclude other combinations,

As a further alternative the concentration of the metal added to the aluminum catalyst material can be changed during the growth. By way of example, without excluding other combinations, growth can be started with added Sb and this can later be exchanged for B. Alternatively, growth can be effected with several changes of the Sb concentration.

1.-16. (canceled)

17. A method of synthesizing a semiconductor nanostructure of at least one semiconductor material by placing one or more solid catalyst particles on a substrate, placing the combination of the said substrate and the said solid catalyst in a chamber of low oxygen partial pressure, below 1×10⁻² mbar, adding one or more gaseous reactants comprising at least one of said semiconductor material and a suitable precursor therefor and heating the said combination to a temperature above 200° C. but below the melting point of the solid catalyst particle wherein the composition of the catalyst particle placed on the substrate comprises more than 50 atomic % of Al, less than 20 atomic % of the semiconductor material and less than 30 atomic % of a combination of a different added metal.

18. The method of claim 17, wherein the semiconductor nanostructure comprises a nanostructure selected from the group consisting of nanowires, nanorods, nanoribbons, nanodots and quantum dots.

19. The method of claim 17, wherein said catalyst particle is aluminum before heating.

20. The method of claim 17, wherein the composition of the catalyst particle placed on the substrate comprises more than 80 atomic % of Al and less than 20 atomic % of the semiconductor material.

21. The method of claim 17, wherein the different added metal is chosen from the group comprising: B, Ga, In, Tl, Li, Sb, P, As, Bi, Te, Ti, Pt, Pd and combinations thereof.

22. The method of claim 17, wherein said substrate is selected to comprise an epitaxial substrate having a surface lattice spacing equal to or approximately equal to that of the semiconductor material in epitaxial form, approximately signifying that the lattice spacing of the substrate surface differs from that of the semiconductor material by at most +/−20%.

23. The method of claim 22, wherein said epitaxial substrate is selected in the form of a semiconductor on insulator substrate.

24. The method of claim 17, wherein the semiconductor material is one of Si, Ge and a combination of Si and Ge.

25. The method of claim 24, wherein the substrate material is selected to be Si.

26. The method of claim 24, wherein the substrate is selected to be Ge.

27. The method of claim 24, wherein the substrate surface is covered by one of Si, Ge and a solid solution of Si and Ge (SiGe), at least at the locations of the one or more solid catalyst particles.

28. The method of claim 17, wherein said substrate is one of an insulating material and a substrate covered by an insulating material.

29. The method of claim 28, wherein said insulating material is selected from the group consisting of: Al₂O₃, CaF₂, SiO₂, SrTiO₃ and CaTiO₃.

30. The method of claim 24, when used to produce one of Si/Ge, Si/SiGe, Ge/SiGe and SiGe/SiGe heterostructure nanostructures, said method comprising the alternate admission of one of the following selected semiconductor material combinations into said chamber in one of vapor form by a PVD process and by using a corresponding precursor in a CVD process:
Si and Ge,
Ge and (Si and Ge),
Si and (Si and Ge) and
Si and Ge in a first ratio and Si and Ge in a second ratio different from the first said ratio, with the simplest possible nanostructure consisting of one of Si and Ge with SiGe.

31. The method of claim 30, wherein said PVD process comprises one of sputtering and vaporization of the selected semiconductor material combination from respective solid targets.

32. The method of claim 30, comprising the step of repeating the procedure of claim 14 with identical or different parameters.

33. The method of claim 32, when operated to produce a superlattice of Si and SiGe by repeating several times Si and SiGe.

34. The method of claim 32, when operated to produce a structure starting with a first SiGe ratio and gradually changing the SiGe ratio.

35. The method of claim 17, wherein the concentration of the different added metal is changed during the growth.

36. The method of claim 35 growth is started with added Sb, latter exchanged by B.

37. The method of claim 35, wherein growth is effected with a plurality of changes of the Sb concentration.

38. A nanostructure selected from the group consisting of nanowire, nanorod, nanoribbon, nanodot and quantum dot and made by a method. of synthesizing the nanostructure of at least one semiconductor material by placing one or more solid catalyst particles on a substrate, placing the combination of the said substrate and the said solid catalyst in a chamber of low oxygen partial pressure, below 1×10⁻² mbar, adding one or more gaseous reactants comprising at least one of said semiconductor material and a suitable precursor therefor and heating the said combination to a temperature above 200° C. but below the melting point of the solid catalyst particle wherein the composition of the catalyst particle placed on the substrate comprises more than 50 atomic % of Al, less than 20 atomic % of the semiconductor material and less than 30 atomic % of a combination of a different added metal.
